(19) United States
(12) Patent Application Publication
(10) Pub. No.: US 2026/0305459 A1
(43) Pub. Date: Oct. 1, 2026

(54) METHOD OF FORMING NON-CONDUCTIVE POLYMER LAYERS WITH A CONTROLLED COEFFICIENT OF THERMAL EXPANSION

(71) Applicant: INPACK TECHNOLOGIES - LIMITED PARTNERSHIP, Migdal HaEmek (IL)

(72) Inventor: Joseph KAPLUN, Petah Tikva (IL)

(21) Appl. No.: 19/479,700

(22) PCT Filed: Apr. 18, 2024
(86) PCT No.: PCT/IL2024/050386

§ 371 Date: Oct. 28, 2025

Related U.S. Application Data
(60) Provisional application No. 63/463,988, filed on May 4, 2023.

(51) Int. Cl. H10W 74/47; C08K 3/22; C08K 3/36; C09D 7/40; C09D 7/61; H10W 74/01

(52) U.S. Cl. CPC H10W 74/473; C09D 7/61; C09D 7/67; H10W 74/01; C08K 2003/2258; C08K 3/36; C08K 2201/011

(57) ABSTRACT

Disclosed herein is a method for forming a semiconductor device including a non-conductive polymer layer with a desired coefficient of thermal expansion (CTE), the method comprising: selecting/obtaining a desired CTE value, formulating a suspension comprising a mixture of dielectric nanoparticles and a curable polymer, the curable polymer is made of or comprises a resin and a hardener; wherein the resin of the curable polymer has a positive CTE, and the dielectric nanoparticles have a different CTE than the resin; wherein the formulating comprises determining a weight ratio the curable polymers and the dielectric nanoparticles, applying the suspension on a surface of a substrate, and curing the suspension to form a non-conductive polymer layer with the desired CTE value.

### TECHNICAL FIELD

The present disclosure, according to some embodiments thereof, relates generally to semiconductor devices, and more particularly, to methods for forming a semiconductor device having a non-conductive polymer layer with a controlled coefficient of thermal expansion.

### BACKGROUND

Non-conductive (dielectric) layers are a crucial component in the functionality, performance and reliability of integrated circuits and semiconductor devices. These layers are used to isolate the various components of the semiconductor device, thereby preventing undesired electrical interactions therebetween. Consequently, ensuring proper operation of the device, minimizing performance degradation and failure. Typically, the non-conductive layers are made of silicon dioxide and are applied/deposited on top of a conductive region/layer, such as copper, aluminum, or other metals. For example, non-conductive layers are implemented in a system-on-a-chip module to separate different layers of the module. In addition to serving as a barrier to prevent electrical signals from passing through it and short-circuiting the different layers of the module, the non-conductive layers may also improve the reliability of the module (or the semiconductor device) by protecting components from moisture, dust, and other contaminants.

### SUMMARY

Aspects of the disclosure, according to some embodiments thereof, relate to semiconductor devices. More specifically, but not exclusively, aspects of the disclosure, according to some embodiments thereof, relate to methods for forming a semiconductor device having a non-conductive polymer layer with a controlled coefficient of thermal expansion (CTE).

Advantageously, the disclosed method enables selecting a desired CTE value of the non-conductive layer, controlling and tailoring the desired CTE according to a design and requirements of the semiconductor device or components/elements thereof.

Advantageously, the disclosed method enables obtaining a matching CTE value to various materials of semiconductor devices and components/elements thereof (e.g., integrated circuits, printed circuit boards, and the like), such as but not limited to, Si, semiconductors made of or comprising III-V compounds of the periodic table, semiconductors made of or comprising II-VI compounds, and the like, or any combination thereof. Consequently, in some embodiments, reducing thermal stress between components of the semiconductor device, facilitating signal integrity, performance, and thermal management, such as heat dissipation, thereof.

Advantageously, the disclosed method enables forming a semiconductor device (e.g., printed circuit board) having a wide variety of non-conductive (dielectric) layers having tailored/controlled values of CTE (such as but not limited to, descending/ascending CTE values thereof), thereby facilitating the performance, reliability and increasing the lifetime of the semiconductor device.

According to some embodiments, there is provided herein a method for forming a semiconductor device comprising a non-conductive polymer layer with a desired coefficient of thermal expansion (CTE), the method including: selecting/obtaining a desired CTE value, formulating a suspension comprising a mixture of dielectric nanoparticles and a curable polymer, the curable polymer is made of or comprises a resin and a hardener, wherein the resin of the curable polymer has a positive CTE, and the dielectric nanoparticles have a different CTE than the resin, wherein the formulating comprises determining a weight ratio the curable polymers and the dielectric nanoparticles, applying the suspension on a surface of a substrate, and curing the suspension to form a non-conductive polymer layer with the desired CTE value.

According to some embodiments, the dielectric nanoparticles have a negative CTE.

According to some embodiments, the CTE of the dielectric nanoparticles may be lower by at least one order of magnitude than the CTE of the resin.

According to some embodiments, the curing may include electron beam radiation.

According to some embodiments, the curing may include applying photon radiation.

According to some embodiments, the photon radiation may include UV radiation.

According to some embodiments, the photon radiation may include heating.

According to some embodiments, the resin of the curable polymer may be made of or include one or more of: an epoxy resin, a polyimide resin, benzocyclobutene (BCB).

According to some embodiments, the dielectric nanoparticles may include Kevlar nanoparticles.

According to some embodiments, the dielectric nanoparticles may include SiO₂ nanoparticles.

According to some embodiments, the dielectric nanoparticles may include α-ZrW₂O₈ nanoparticles.

According to some embodiments, the dielectric nanoparticles may include β-ZrW₂O₈ nanoparticles.

According to some embodiments, the selecting/obtaining may include the desired CTE of about 17 ppm/°C, thereby matching a CTE of copper (Cu).

According to some embodiments, the selecting/obtaining may include the desired CTE of about 20 ppm/°C, thereby matching a CTE of silver (Ag).

According to some embodiments, the selecting/obtaining may include the desired CTE of about 23 ppm/°C, thereby matching a CTE of aluminum (Al).

According to some embodiments, the selecting/obtaining may include the desired CTE of about 3.5 ppm/°C, thereby matching a CTE of silicon (Si).

According to some embodiments, the selecting/obtaining may include the desired CTE of about 7.2 ppm/°C, thereby matching a CTE of gallium arsenide (GaAs).

According to some embodiments, the selecting/obtaining may include the desired CTE of about 8 ppm/°C, thereby matching a CTE of indium phosphide (InP).

According to some embodiments, the selecting/obtaining may include the desired CTE of about 5 ppm/°C, thereby matching a CTE of any one of: aluminum nitride (AlN), gallium nitride (GaN), 3C, 4H and/or 6H silicon carbide (SiC).

According to some embodiments, the method may further include removing an excess portion of the non-conductive polymer layer.

According to some embodiments, the method may further include planarizing the non-conductive polymer layer.

According to some embodiments, there is provided herein a semiconductor or a component thereof including a dielectric layer having a controlled coefficient of thermal expansion (CTE), the dielectric layer including a mixture of dielectric nanoparticles and a curable polymer, the curable polymer including a resin and a hardener; wherein the resin of the curable polymer has a positive CTE; and wherein the dielectric nanoparticles have a different CTE than the resin.

According to some embodiments, the dielectric nanoparticles of the semiconductor device or component thereof may include Kevlar nanoparticles.

According to some embodiments, the dielectric nanoparticles of the semiconductor device or component thereof may include SiO₂ nanoparticles.

According to some embodiments, the dielectric nanoparticles of the semiconductor device or component thereof may include α-ZrW₂O₈ nanoparticles.

According to some embodiments, the dielectric nanoparticles of the semiconductor device or component thereof may include β-ZrW₂O₈ nanoparticles.

Unless otherwise defined, all technical and scientific terms used herein have the same meaning as commonly understood by one of ordinary skill in the art to which this disclosure pertains. In case of conflict, the patent specification, including definitions, governs. As used herein, the indefinite articles “a” and “an” mean “at least one” or “one or more” unless the context clearly dictates otherwise.

### BRIEF DESCRIPTION OF THE FIGURES

Some embodiments of the disclosure are described herein with reference to the accompanying figures. The description, together with the figures, makes apparent to a person having ordinary skill in the art how some embodiments may be practiced. The figures are for the purpose of illustrative description and no attempt is made to show structural details of an embodiment in more detail than is necessary for a fundamental understanding of the disclosure. For the sake of clarity, some objects depicted in the figures are not drawn to scale. Moreover, two different objects in the same figure may be drawn to different scales. In particular, the scale of some objects may be greatly exaggerated as compared to other objects in the same figure.

In the figures:

FIG. 1 schematically illustrates an example of a method for manufacturing a semiconductor device comprising a non-conductive polymer layer with a desired coefficient of thermal expansion (CTE), according to some embodiments.

### DETAILED DESCRIPTION

The principles, uses, and implementations of the teachings herein may be better understood with reference to the accompanying description and figures. Upon perusal of the description and figures present herein, one skilled in the art will be able to implement the teachings herein without undue effort or experimentation.

In the description and claims of the application, the words “include” and “have”, and forms thereof, are not limited to members in a list with which the words may be associated.

As used herein, the term “about” may be used to specify a value of a quantity or parameter (e.g. the length of an element) to within a continuous range of values in the neighborhood of (and including) a given (stated) value. According to some embodiments, “about” may specify the value of a parameter to be between 80% and 120% of the given value. For example, the statement “the length of the element is equal to about 1 m” is equivalent to the statement “the length of the element is between 0.8 m and 1.2 m”. According to some embodiments, “about” may specify the value of a parameter to be between 90% and 110% of the given value. According to some embodiments, “about” may specify the value of a parameter to be between 95% and 105% of the given value.

As used herein, according to some embodiments, the terms “substantially” and “about” may be interchangeable.

As used herein, according to some embodiments the term “electronic device” may refer to any device including electronic components therein, such as, but not limited to, a wearable device (e.g., a smart watch, a fitness tracker, and the like), a mobile phone (e.g., a smartphone), a tablet, a computer (e.g., a laptop), a camera, a screen (e.g., a touch screen), a television, a robot (e.g., a robotic arm, and the like), a memory device, a power storage device, a light-emitting device, and the like. Each possibility is a separate embodiment. According to some embodiments, the electronic device may be portable. According to some embodiments, the electronic device may refer to a non-mobile device. According to some embodiment, the electronic device may refer to a household appliance, an industrial appliance/system, a car, and the like. Each possibility is a separate embodiment.

As used herein, according to some embodiments, the terms “electronic device” and “semiconductor device” may be interchangeably.

According to some embodiments, the semiconductor device may include semiconductor dies, chips, integrated circuits, modules (such as but not limited to, system on a chip, system in a package, package on a package, system/computer on a module, and the like), core components (e.g., processor cores), communication interfaces, memory blocks, and the like, or any combination thereof. Each possibility is a separate embodiment.

As used herein, according to some embodiments, the term “component of a semiconductor device” may refer to any section, portion, or an element of the semiconductor device having or being connected/attached to an insulating/dielectric material. According to some embodiments, the term “component of a semiconductor device” refer to, among others, a die (e.g., transistor or portions thereof), a chip, a chip carrier, a passive component, an active component, an interconnecting section/component (e.g., interposer, contact pads, lines, traces, vias, and the like), an interface, a module (e.g., chip module), a semiconductor package or components thereof, a substrate, and the like, or any combination thereof. Each possibility is a separate embodiment. According to some embodiments, the term “component of a semiconductor device” may refer to an interposer. According to some embodiments, the term “component of a semiconductor device” may refer to any portion/component of a printed circuit board. According to some embodiments, the term “component of a semiconductor device” may refer to any portion/component/element of an integrated circuit. Each possibility is a separate embodiment. According to some embodiments, the term “component of a semiconductor device” may refer to any portion/component of an RF circuit.

According to some embodiments, there is provided herein a method for forming a non-conductive polymer layer with a controlled coefficient of thermal expansion (CTE), the method including: selecting/obtaining a desired CTE value, formulating a suspension including a mixture of dielectric nanoparticles and a curable polymer, the curable polymer is made of or includes a resin and a hardener, wherein the resin of the curable polymer has a positive CTE, and the dielectric nanoparticles have a different CTE than the resin, wherein the formulating comprises determining a weight ratio between the curable polymers and the dielectric nanoparticles, applying the suspension on a surface of a substrate, and curing the suspension to form a non-conductive polymer layer with the desired CTE value.

According to some embodiments, size (e.g., diameter, longest cross-sectional dimension, or any other dimension) of the dielectric nanoparticles may be about 250 nm or less. According to some embodiment, size of the dielectric nanoparticles may be in a range of about 100 nm to about 250 nm, about 150 nm to about 250 nm, about 5 nm to about 200 nm, about 5 nm to about 250 nm, about 20 nm to about 200 nm, about 5 nm to about 100 nm, about 5 nm to about 150 nm. Each possibility is a separate embodiment.

According to some embodiments, size of the dielectric nanoparticles may be about 250 nm or less, about 200 nm or less, about 150 nm or less, about 100 nm or less, about 50 nm or less. Each possibility is a separate embodiment.

According to some embodiments, the disclosed method advantageously enables obtaining a matching CTE value to various materials of integrated circuits, such as but not limited to, Si, semiconductors made of or comprising III-V compounds of the periodic table (e.g., GaAs, GaSb, GaN, AlN, InP, and the like), SiC (e.g., 3C SiC, 4H SiC, 6H SiC), and the like, or any combination thereof. Each possibility is a separate embodiment. According to some embodiments, the III-V compounds may include, among others, binary, ternary, and/or quaternity compounds, wherein at least one element is from main group III and at least one element from main group V of the periodic table. Each possibility is a separate embodiment. According to some embodiments, the disclosed method advantageously enables obtaining a matching CTE value to semiconductors made of or comprising II-VI compounds of the periodic table. Each possibility is a separate embodiment.

According to some embodiments, the disclosed method enables obtaining a matching CTE to various materials of integrated circuits, such as but not limited to, copper (Cu), silver (Ag), aluminium (Al), and the like, or any combination thereof. Each possibility is a separate embodiment. According to some embodiments, the disclosed method enables tailoring the CTE of the non-conductive polymer layer, thereby facilitating thermal properties/thermal management (such as but not limited to heat dissipation) of the semiconductor device.

Advantageously, in some embodiments, matching the CTE in integrated circuits facilitates minimizing/preventing thermal stress between one or more electronic components or elements thereof in an electronic device, thereby minimizing/preventing cracking, warpage, and/or undesired deformation and/or defects (e.g., bending, twisting, and the like) of electronic components/elements of the electronic device, thereby enhancing the performance, the yield and the reliability of the electronic device. Each possibility is a separate embodiment.

Advantageously, in some embodiments, tailoring the CTE enables incorporating various materials in an electronic device obtaining matching CTEs with various components thereof, thereby enhancing the performance and the yield of the electronic device. As a non-limiting example, incorporating various materials may include incorporating various types of chips, such as different generations, materials, and the like, in an integrated circuit and/or in a semiconductor/electronic device.

Advantageously, in some embodiments, adjusting/tailoring the CTE of the non-conductive polymer layer facilitates the thermal management (i.e., facilitates heat dissipation) of the electronic device.

Advantageously, in some embodiments, adjusting/tailoring the CTE of the non-conductive polymer layer minimizes thermal stress between one or more components (such as, but not limited to, dies, chips, integrated circuits, passive/active components, traces, contact pads, and the like or any elements thereof) of the electronic device. According to some embodiments, this may improve the performance, signal integrity and durability of the electronic device. In some embodiments, adjusting/tailoring the CTE of the non-conductive layer may be particularly important in RF circuits, such as but not limited to, printed RF circuits (e.g., operating/supporting frequency range of about 100 MHz to about 300 GHz), and the like, to facilitate RF signal propagation and signal integrity thereof.

According to some embodiments, there is provided herein a method for forming a non-conductive polymer layer with a controlled/adjustable coefficient of thermal expansion (CTE), the method including: selecting/obtaining a desired CTE value, formulating a suspension including a mixture of dielectric nanoparticles and a curable polymer, wherein the dielectric nanoparticles include Kevlar nanoparticles, and the curable polymer is made of or includes a resin and a hardener, wherein the resin of the curable polymer has a positive CTE, and the dielectric nanoparticles have a different CTE than the resin, wherein the formulating comprises determining a weight ratio between the curable polymers and the dielectric nanoparticles, applying the suspension on a surface of a substrate, and curing the suspension to form a non-conductive polymer layer with the desired CTE value.

According to some embodiments, there is provided herein a method for forming a non-conductive polymer layer with a controlled/adjustable coefficient of thermal expansion (CTE), the method including: selecting/obtaining a desired CTE value, formulating a suspension including a mixture of dielectric nanoparticles and a curable polymer, wherein the dielectric nanoparticles include α-ZrW₂O₈ nanoparticles, and the curable polymer is made of or includes a resin and a hardener, wherein the resin of the curable polymer has a positive CTE, and the dielectric nanoparticles have a different CTE than the resin, wherein the formulating comprises determining a weight ratio between the curable polymers and the dielectric nanoparticles, applying the suspension on a surface of a substrate, and curing the suspension to form a non-conductive polymer layer with the desired CTE value.

According to some embodiments, there is provided herein a method for forming a non-conductive polymer layer with a controlled/adjustable thermal expansion coefficient (CTE), the method including: selecting/obtaining a desired CTE value, formulating a suspension including a mixture of dielectric nanoparticles and a curable polymer, wherein the dielectric nanoparticles include β-ZrW₂O₈ nanoparticles, and the curable polymer is made of or includes a resin and a hardener, wherein the resin of the curable polymer has a positive CTE, and the dielectric nanoparticles have a different CTE than the resin, wherein the formulating comprises determining a weight ratio between the curable polymers and the dielectric nanoparticles, applying the suspension on a surface of a substrate, and curing the suspension to form a non-conductive polymer layer with the desired CTE value.

According to some embodiments, there is provided herein a method for forming a non-conductive polymer layer with a controlled/adjustable thermal expansion coefficient (CTE), the method including: selecting/obtaining a desired CTE value, formulating a suspension including a mixture of dielectric nanoparticles and a curable polymer, wherein the dielectric nanoparticles include SiO₂ nanoparticles, and the curable polymer is made of or includes a resin and a hardener, wherein the resin of the curable polymer has a positive CTE, and the dielectric nanoparticles have a different CTE than the resin, wherein the formulating comprises determining a weight ratio between the curable polymers and the dielectric nanoparticles, applying the suspension on a surface of a substrate, and curing the suspension to form a non-conductive polymer layer with the desired CTE value.

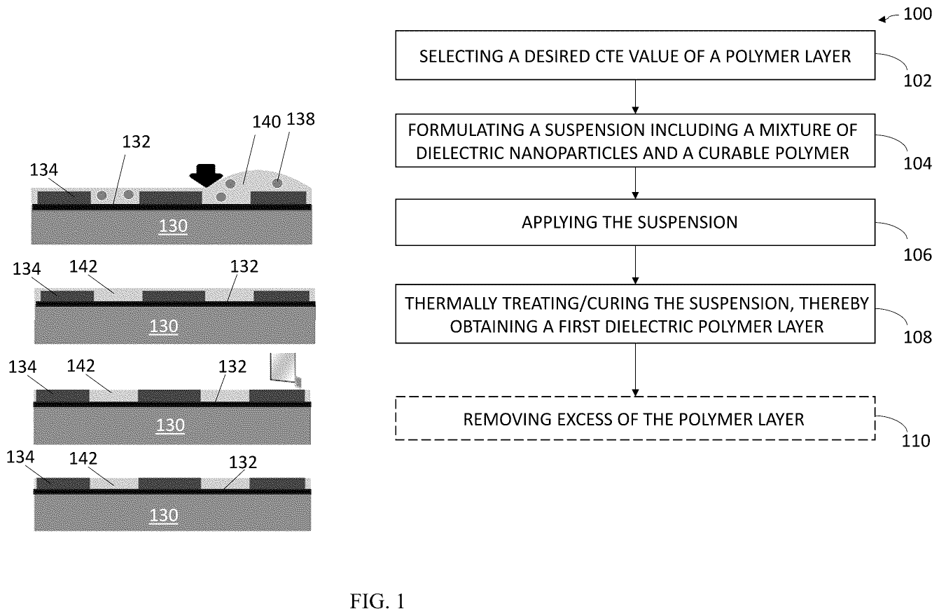

Reference is now made to FIG. 1, which schematically illustrates a flowchart 100 of a method for manufacturing a semiconductor device comprising a non-conductive polymer layer with a desired coefficient of thermal expansion (CTE), according to some embodiments.

According to some embodiments, at step 102, the method may include selecting/obtaining a desired value of the CTE of a non-conductive polymer layer.

According to some embodiments, selecting/obtaining the desired CTE value may be based, at least in part of, among others, on materials incorporated/included in an electronic device or components thereof (such as but not limited to, materials forming an integrated circuit, electronic elements, die/chip, chip module, and the like, or any combination thereof). According to some embodiments, selecting/obtaining the CTE value may be based, among others, the desired properties of the electronic device. According to some embodiments, the desired properties of the electronic device may include, among others, power consumption, yield, speed, heat dissipation requirements, and the like, or any combination thereof. Each possibility is a separate embodiment.

According to some embodiments, the desired CTE value may be configured to match to various materials of integrated circuits, such as but not limited to, Si, III-V compounds of the periodic table (e.g., GaAs, GaSb, GaN, AlN, InP, and the like), SiC (e.g., (e.g., 3C SiC, 4H SiC, 6H SiC), and the like, or any combination thereof. Each possibility is a separate embodiment. According to some embodiments, the desired CTE value may match to a CTE of various materials of integrated circuits, such as but not limited to, copper (Cu), silver (Ag), aluminium (Al), and the like, or any combination thereof. Each possibility is a separate embodiment.

According to some embodiments, the desired CTE value of the polymer layer may be in a range of about 1-30 ppm/°C, about 3-30 ppm/°C, about 10-30 ppm/°C, about 15-30 ppm/°C, about 1-25 ppm/°C, about 15-25 ppm/°C, about 1-15 ppm/°C, about 1-20 ppm/°C, about 1-10 ppm/°C, about 2-10 ppm/°C, about 2-25 ppm/°C, about 2-8 ppm/°C, or any other desired/required value. Each possibility is a separate embodiment.

According to some embodiments, the desired CTE value of the polymer layer may be about 3 ppm/°C, about 4 ppm/°C, about 5 ppm/°C, about 3-6 ppm/°C, about 7-8 ppm/°C, about 17 ppm/°C, about 20 ppm/°C, about 23 ppm/°C, and the like. Each possibility is a separate embodiment.

According to some embodiments, the desired CTE value of the polymer layer may be about 17 ppm/°C, thereby matching a CTE of copper (Cu). According to some embodiments, the desired CTE value of the polymer layer may be about 20 ppm/°C, thereby matching a CTE of silver (Ag). According to some embodiments, the desired CTE value of the polymer layer may be about 23 ppm/°C, thereby matching a CTE of aluminium (Al). According to some embodiments, the desired CTE value of the polymer layer may be about 3.5 ppm/°C, thereby matching a CTE of silicon (Si). According to some embodiments, the desired CTE value of the polymer layer may be about 7.2 ppm/°C, thereby matching a CTE of gallium arsenide (GaAs). According to some embodiments, the desired CTE value of the polymer layer may be about 8 ppm/°C, thereby matching a CTE of indium phosphide (InP). According to some embodiments, the desired CTE value of the polymer layer may be about 5 ppm/°C, thereby matching a CTE of any one of: aluminum nitride (AlN), gallium nitride (GaN), 3C, 4H and/or 6H silicon carbide (SiC). Each possibility is a separate embodiment.

According to some embodiments, at step 104, the method may include formulating a suspension (e.g., a suspension 140, as depicted in FIG. 1). According to some embodiments, the suspension includes a mixture of dielectric nanoparticles 138 and a curable polymer. According to some embodiments, the curable polymer may be made of or include a resin and a hardener.

According to some embodiments, the formulating includes determining a ratio between the curable polymer and the dielectric nanoparticles 138. According to some embodiments, the ratio may be, among others, a mole ratio. According to some embodiments, the ratio may be, among others, a weight ratio. According to some embodiments, the ratio may be, among others, an atomic ratio. Each possibility is a separate embodiment.

According to some embodiments, the ratio between the curable polymer and the dielectric nanoparticles 138 may include any value in a range of about 5% to about 95% of the curable polymer. According to some embodiments, the range may include, among others, about 5% to about 20%, about 5% to about 50%, about 20% to about 80%, about 5% to about 90%, about 30% to about 50% of the curable polymer. Each possibility is a separate embodiment.

According to some embodiments, the ratio between the curable polymer and dielectric nanoparticles 138 may be about 60% to about 80% of the curable polymer and about 40% to about 20%, respectively, of dielectric nanoparticles 138. According to some embodiments, the ratio between the curable polymer and dielectric nanoparticles 138 may be about 5% to about 10% of the curable polymer and about 95% to about 90%, respectively, of dielectric nanoparticles 138. Each possibility is a separate embodiment.

According to some embodiments, the ratio between the curable polymer and dielectric nanoparticles 138 may be about 1:30, about 1:25, about 1:20, about 1:10, about 1:9, about 1:8, about 1:7, about 1:6, about 1:5, about 1:4, about 1:3, about 1:2, about 3:7, about 2:3, about 1:1, and any reciprocal ratio thereof. Each possibility is a separate embodiment.

According to some embodiments, dielectric nanoparticles 138 may have a positive CTE. According to some embodiments, dielectric nanoparticles 138 may have a negative CTE. Each possibility is a separate embodiment.

According to some embodiments, the resin of the curable polymer may have a positive CTE, while the dielectric nanoparticles have a different CTE than the resin.

According to some embodiments, the CTE of dielectric nanoparticles 138 may be lower than the CTE of the resin. According to some embodiments, the CTE of dielectric nanoparticles 138 may be lower than the CTE of the resin by about: at least one order of magnitude, at least two orders of magnitude, at least three orders of magnitude, at least four orders of magnitude, at least five orders of magnitude, or more. Each possibility is a separate embodiment. According to some embodiments, the CTE of dielectric nanoparticles 138 may be lower than the CTE of the resin by about one order of magnitude to about four orders of magnitude. According to some embodiments, the CTE of dielectric nanoparticles 138 may be lower than the CTE of the resin by about one order of magnitude to about three orders of magnitude. According to some embodiments, the CTE of dielectric nanoparticles 138 may be lower than the CTE of the resin by about one order of magnitude to about two orders of magnitude. Each possibility is a separate embodiment.

According to some embodiments, dielectric nanoparticles 138 may be made of or include Kevlar nanoparticles. According to some embodiments, the dielectric nanoparticles may be made of or include SiO₂ nanoparticles. According to some embodiments, the dielectric nanoparticles may be made of or include α-ZrW₂O₈ nanoparticles.

According to some embodiments, dielectric nanoparticles 138 may be made of or include β-ZrW₂O₈ nanoparticles. According to some embodiments, dielectric nanoparticles 138 may be made of or include one or more of: Kevlar, SiO₂, α-ZrW₂O₈, β-ZrW₂O₈ nanoparticles. Each possibility is a separate embodiment.

According to some embodiments, the resin of the curable polymer may be made of or include an epoxy resin. According to some embodiments, the resin of the curable polymer may be made of or include a polyimide resin. According to some embodiments, the resin of the curable polymer may be made of or include benzocyclobutene (BCB). Each possibility is a separate embodiment.

According to some embodiments, the resin of the curable polymer may be made of or include one or more of: an epoxy resin, a polyimide resin, (BCB). Each possibility is a separate embodiment.

According to some embodiments, at step 106, the method may include applying suspension 140 on a semiconductor device or a portion/component thereof. As a non-limiting example, suspension 140 may be applied, among others, on a substrate, conductive portions/elements such as traces, pads, and the like, or any other passive/active components, dies, and the like, or any combination thereof.

According to some embodiments, and as depicted in FIG. 1, the method may include applying suspension 140 on a substrate 130. According to some embodiments, substrate 130 may be an inert substrate. According to some embodiments, substrate 130 may be made of or include, among others, glass (e.g., coated glass, uncoated glass, and the like), Si, ceramic materials, polymers, stainless steels, and the like, or any combination thereof. Each possibility is a separate embodiment.

According to some embodiments, substrate 130 may be rigid. As a non-limiting example, wherein substrate 130 is rigid, a Shore hardness thereof may be in a range of about 85 D-96 D. According to some embodiments, substrate 130 may be flexible/bendable. As a non-limiting example, wherein substrate 130 is flexible/bendable, a Shore hardness thereof may be in a range of about 45 D-70 D. According to some embodiments, substrate 130 may be semi-rigid (e.g., of a combined hardness of the rigid and the flexible substrates). Each possibility is a separate embodiment.

According to some embodiments, substrate 130 may be a temporary substrate (i.e., removable/detachable substrate). Alternatively, in some embodiments, substrate 130 may be a non-temporary substrate.

According to some embodiments, substrate 130 may optionally be a coated substrate. According to some embodiments, a coating of substrate 130 may facilitate adhesion of conductive lines. According to some embodiments, coating 132 of substrate 130 may be made of or include, among others, a seed layer of TiW and Cu. According to some embodiments, coating 132 may include an adhesive. As a non-limiting example, the adhesive may include a permanent adhesive film/layer. According to some embodiments, coating 132 may include a die attach film. According to some embodiments, coating 132 may include a thermal interface material.

According to some embodiments, substrate 130 may be uncoated. Put differently, in some embodiments, substrate 130 may be devoid of coating 132.

According to some embodiments, substrate 130 may optionally include one or more electrically conductive lines/pads 134. According to some embodiments, one or more electrically conductive lines/pads 134 are configured to electrically interconnect an integrated circuit (e.g., analog integrated circuits, RF integrated circuits, and the like) to external components, input/output devices, thereby allowing signals transmission between electronic components. According to some embodiments, electrically conductive lines/pads 134 may be configured to enable signals transmission between dies, chips, passive or active components such as inductors and/or capacitors, processors, and the like, or any combination thereof.

According to some embodiments, substrate 130 may be made of or include a system in a package module (or a section/component thereof), and suspension 140 may be applied during one or more steps of a manufacturing process thereof. As a non-limiting example, suspension 140 may be applied on at least a section of substrate 130, wherein substrate 130 includes an interconnecting structure, such as an interposer. It may be understood by skilled in the art that the suspension may be applied at any step of manufacturing of the electronic device (e.g., any step requiring forming a dielectric region/layer during the electronic device manufacturing process).

According to some embodiments, applying suspension 140 may include pouring suspension 140 (e.g., on an electronic device or a section thereof, on a temporary carrier, a substrate, and the like) during the manufacturing process. According to some embodiments, applying suspension 140 may optionally include using a spin coater or any other tool/device, to facilitate forming a substantially uniform layer of suspension 140 on substrate 130.

According to some embodiments, at step 108, the method may include curing suspension 142, thereby obtaining a first non-conductive (dielectric) polymer layer 142. According to some embodiments, at step 108, the method may include thermally treating suspension 142, thereby obtaining a first non-conductive (dielectric) polymer layer 142. According to some embodiments, at step 108, the method may include polymerizing suspension 142, thereby obtaining a first non-conductive (dielectric) polymer layer 142.

According to some embodiments, curing suspension 142 may include, among others, one or more of: applying electron beam radiation, photon radiation (such as but not limited to ultraviolet (UV) radiation, heating/thermal radiation, and the like) of suspension 142. Each possibility is a separate embodiment.

According to some embodiments, heating of suspension 142 may be performed, among others, at any temperature in a range of about 100 °C to about 300 °C, about 100 °C to about 200 °C, about 150 °C to about 300 °C, about 200 °C to about 300 °C, about 150 °C to about 250 °C. Each possibility is a separate embodiment.

According to some embodiments, heating of suspension 142 may be performed, among others, for about 3 minutes to about 3 hours, about 3 minutes to about 1 hour, about 5 minutes to about 2 hours, about 3 minutes to about 30 minutes, about 3 minutes to about 10 minutes, about 1 hour to about 3 hours, about 30 minutes to about 1.5 hours, about 20 minutes to about 1 hour, about 2 hours to about 3 hours. Each possibility is a separate embodiment.

As a non-limiting example, curing suspension 142 may include, among others, heating suspension 142 at about 120 °C for about 4 minutes. As another non-limiting example, curing suspension 142 may include, among others, heating suspension 142 at about 250 °C for about 3 minutes.

According to some embodiments, at step 110, the method may optionally include removing/scraping an excess portion of polymer layer 142.

According to some embodiments, removing/scraping off the excess portion of polymer layer 142 may include planarizing using a surface planer device/machine, such that a substantially flat surface of the first layer (and/or of each of additional one or more layers) of polymer layer 142 is formed. According to some embodiments, and as depicted in FIG. 1, the excess of polymer layer 142 may be removed until a portion one or more electrically conductive lines/pads 134 (e.g., surface or top layer thereof) is exposed, thereby allowing electrical conductivity while preventing short-circuits therebetween.

According to some embodiments, the method may include repeating at least a portion of the abovementioned steps to produce additional one or more layers of non-conductive (dielectric) polymer. As a non-limiting example, the steps may be repeated to produce a multi-layered structure of an electronic component. Put differently, at least a portion of the abovementioned steps may be repeated until the required number of a plurality of non-conductive (i.e., insulating) layers is obtained (e.g., until the required height/depth of the polymer layers is achieved).

According to some embodiments, each of the one or more non-conductive (dielectric) polymer layers may have a substantially same CTE value. According to some embodiments, at least a portion of the one or more non-conductive (dielectric) polymer layers of have a different CTE value. As a non-limiting example, each of the one or more non-conductive (dielectric) polymer layers may have ascending, descending or alternating CTE values. Each possibility is a separate embodiment.

According to some embodiments, the repeating may optionally include aligning non-conductive regions of a previous/bottom layer of the plurality of non-conductive layers with an additional layer of the plurality of non-conductive layers.

According to some embodiments, the method may provide an “on-the-fly” formation of a plurality of non-conductive regions (formed by polymer 142) between electrically conductive material (e.g., as depicted in FIG. 1).

According to some embodiments, the method enables forming the plurality of non-conductive regions according to a predefined pattern (e.g., present on substrate 130). According to some embodiments, a wide range of complex and/or high-density patterns of the non-conductive regions may be obtained, thereby allowing, for example, achieving a wide variety of signal routing.

Although stages of methods, according to some embodiments, may be described in a specific sequence, the methods of the disclosure may include some or all of the described stages carried out in a different order. In particular, it is to be understood that the order of stages and sub-stages of any of the described methods may be reordered unless the context clearly dictates otherwise, for example, when a latter stage requires as input an output of a former stage or when a latter stage requires a product of a former stage. A method of the disclosure may include a few of the stages described or all of the stages described. No particular stage in a disclosed method is to be considered an essential stage of that method, unless explicitly specified as such.

According to some embodiments, there is provided herein a semiconductor device or a component thereof including a dielectric layer having a controlled coefficient of thermal expansion (CTE), the dielectric layer including a mixture of dielectric nanoparticles and a curable polymer, the curable polymer including a resin and a hardener; wherein the resin of the curable polymer has a positive CTE; and wherein the dielectric nanoparticles have a different CTE than the resin.

According to some embodiments, the semiconductor device or the component thereof may include, among others, an integrated circuit, an interposer, a die/chip, an interface, a printed circuit board, and the like or any combination thereof. Each possibility is a separate embodiment.

According to some embodiments, the semiconductor device or the component thereof may include, among others, a multi-layered structure, a patterned structure, and the like, or a combination thereof.

According to some embodiments, the dielectric nanoparticles of the semiconductor device or component thereof may include one or more of: Kevlar nanoparticles, SiO₂ nanoparticles, α-ZrW₂O₈ nanoparticles, β-ZrW₂O₈ nanoparticles. Each possibility is a separate embodiment.

According to some embodiments, the dielectric layer of the semiconductor device may be manufactured by “in-the-fly” formation, e.g., as described in greater detail in FIG. 1.

Although the disclosure is described in conjunction with specific embodiments thereof, it is evident that numerous alternatives, modifications, and variations that are apparent to those skilled in the art may exist. Accordingly, the disclosure embraces all such alternatives, modifications, and variations that fall within the scope of the appended claims. It is to be understood that the disclosure is not necessarily limited in its application to the details of construction and the arrangement of the components and/or methods set forth herein. Other embodiments may be practiced, and an embodiment may be carried out in various ways.

The phraseology and terminology employed herein are for descriptive purpose and should not be regarded as limiting. Citation or identification of any reference in this application shall not be construed as an admission that such reference is available as prior art to the disclosure. Section headings are used herein to ease understanding of the specification and should not be construed as necessarily limiting.

1.-25. (canceled)

26. A method for forming a semiconductor device comprising a non-conductive polymer layer with a desired coefficient of thermal expansion (CTE), the method comprising:
selecting/obtaining a desired CTE value;
formulating a suspension comprising a mixture of dielectric nanoparticles and a curable polymer, the curable polymer is made of or comprises a resin and a hardener; wherein the resin of the curable polymer has a positive CTE, and the dielectric nanoparticles have a different CTE than the resin; wherein the formulating comprises determining a weight ratio the curable polymers and the dielectric nanoparticles;
applying the suspension on a surface of a substrate; and
curing the suspension to form a non-conductive polymer layer with the desired CTE value.

27. The method of claim 26, wherein the dielectric nanoparticles have a negative CTE and wherein the CTE of the dielectric nanoparticles is lower by at least one order of magnitude than the CTE of the resin.

28. The method of claim 26, wherein the curing comprises electron beam radiation.

29. The method of claim 26, wherein the curing comprises applying photon radiation wherein the photon radiation comprises UV radiation or heating.

30. The method of claim 26, wherein the resin of the curable polymer is made of or comprises one or more of: an epoxy resin, a polyimide resin, benzocyclobutene (BCB).

31. The method of claim 26, wherein the dielectric nanoparticles comprise Kevlar nanoparticles.

32. The method of claim 26, wherein the dielectric nanoparticles comprise SiO₂ nanoparticles.

33. The method of claim 26, wherein the dielectric nanoparticles comprise α-ZrW₂O₈ nanoparticles.

34. The method of claim 26, wherein the dielectric nanoparticles comprise β-ZrW₂O₈ nanoparticles.

35. The method of claim 26, wherein the selecting/obtaining comprises the desired CTE of about 17 ppm/°C, thereby matching a CTE of copper (Cu).

36. The method of claim 26, wherein the selecting/obtaining comprises the desired CTE of about 20 ppm/°C, thereby matching a CTE of silver (Ag).

37. The method of claim 26, wherein the wherein the selecting/obtaining comprises the desired CTE of about 23 ppm/°C, thereby matching a CTE of aluminum (Al).

38. The method of claim 26, wherein the selecting/obtaining comprises the desired CTE of about 3.5 ppm/°C, thereby matching a CTE of silicon (Si).

39. The method of claim 26, wherein the selecting/obtaining comprises the desired CTE of about 7.2 ppm/°C, thereby matching a CTE of gallium arsenide (GaAs).

40. The method of claim 26, wherein the selecting/obtaining comprises the desired CTE of about 8 ppm/°C, thereby matching a CTE of indium phosphide (InP).

41. The method of claim 26, wherein the selecting/obtaining comprises the desired CTE of about 5 ppm/°C, thereby matching a CTE of any one of: aluminum nitride (AlN), gallium nitride (GaN), 3C, 4H and/or 6H silicon carbide (SiC).

42. The method of claim 26, further comprising removing an excess portion of the non-conductive polymer layer.

43. A semiconductor device or a component thereof, comprising:
a dielectric layer having a controlled coefficient of thermal expansion (CTE), the dielectric layer comprising a mixture of dielectric nanoparticles and a curable polymer, the curable polymer comprising a resin and a hardener; wherein the resin of the curable polymer has a positive CTE; and wherein the dielectric nanoparticles have a different CTE than the resin.

44. The semiconductor device or component thereof of claim 43, wherein the dielectric nanoparticles comprise Kevlar nanoparticles, SiO₂ nanoparticles, or β-ZrW₂O₈ nanoparticles.
